(19) United States
(12) Patent Application Publication
(10) Pub. No.: US 2025/0240959 A1
(43) Pub. Date: Jul. 24, 2025

(54) SEMICONDUCTOR MEMORY DEVICE

(71) Applicant: Kioxia Corporation, Tokyo (JP)

(72) Inventors: Shizuka KUTSUKAKE, Kuwana Mie (JP); Ikuya SAIKI, Mie Mie (JP); Hiroshi NAKAKI, Yokkaichi Mie (JP)

(73) Assignee: Kioxia Corporation, Tokyo (JP)

(21) Appl. No.: 18/827,677

(22) Filed: Sep. 7, 2024

(30) Foreign Application Priority Data
Jan. 19, 2024 (JP) 2024-006829

(51) Int. Cl. H10B 43/27; H10B 41/27

(52) U.S. Cl. CPC H10B 43/27; H10B 41/27

(57) ABSTRACT

According to an embodiment, a semiconductor memory device includes first to fifth memory pillars, third to seventh contact plugs respective provided on the first to fifth memory pillars. A first shift amount obtained by shifting the third contact plug in the second direction with respect to the first memory pillar, a second shift amount obtained by shifting the fourth contact plug in the second direction with respect to the second memory pillar, a third shift amount obtained by shifting the fifth contact plug in the second direction with respect to the third memory pillar, a fourth shift amount obtained by shifting the sixth contact plug in the second direction with respect to the fourth memory pillar, and a fifth shift amount obtained by shifting the seventh contact plug in the second direction with respect to the fifth memory pillar are different from each other.

### CROSS-REFERENCE TO RELATED APPLICATION

This application is based upon and claims the benefit of priority from Japanese Patent Application No. 2024-006829, filed Jan. 19, 2024, the entire contents of which are incorporated herein by reference.

### FIELD

Embodiments described herein relate generally to a semiconductor memory device.

### BACKGROUND

As a semiconductor memory device, a three-dimensional stacked NAND flash memory is known.

### BRIEF DESCRIPTION OF DRAWINGS

FIG. 1 is a block diagram illustrating an example of a semiconductor memory device according to an embodiment.

FIG. 2 is a circuit diagram illustrating an example of a circuit configuration of a memory cell array included in the semiconductor memory device according to the embodiment.

FIG. 3 is a plan view illustrating an example of the memory cell array included in the semiconductor memory device according to the embodiment.

FIG. 4 is an enlarged plan view of a region V1 in FIG. 3.

FIG. 5 is a cross-sectional view of a memory area taken along a line V2-V2 illustrated in FIG. 4.

FIG. 6 is a cross-sectional view taken along a line V4-V4 in FIG. 5.

FIG. 7 is a diagram illustrating an example of a positional relationship among a memory pillar, contact plugs CH and VY, and bit lines in the presence or absence of a CH shift.

FIG. 8 is an enlarged plan view of a region V3 in FIG. 4.

FIG. 9 is a table illustrating an example of a CH shift amount in one block BLK included in the semiconductor memory device according to the embodiment.

FIG. 10 is a cross-sectional view illustrating an example of an upper portion of the memory pillar, the contact plug CH, and the contact plug VY included in the semiconductor memory device according to the embodiment.

FIG. 11 is a plan view of an upper end of the memory pillar included in the semiconductor memory device according to the embodiment.

FIG. 12 is a plan view of an upper end of the contact plug CH included in the semiconductor memory device according to the embodiment.

### DETAILED DESCRIPTION

In general, according to one embodiment, a semiconductor memory device includes a source line, a plurality of insulating layers, a plurality of interconnect layers, a plurality of memory pillars, a plurality of bit lines, a plurality of first contact plugs, a plurality of second contact plugs, and a plurality of first members. The plurality of insulating layers and the plurality of interconnect layers are provided on the source line and alternately stacked one by one. The plurality of memory pillars extend in a first direction, pass through the plurality of insulating layers and the plurality of interconnect layers, and have one end reaching the source line. The plurality of bit lines are provided above the plurality of memory pillars, are arranged side by side in a second direction intersecting the first direction, and each extends in a third direction intersecting the first direction and the second direction. The plurality of first contact plugs are provided on the plurality of memory pillars. The plurality of second contact plugs are provided on the plurality of first contact plugs and each coupled to one of the plurality of bit lines. The plurality of first members are arranged side by side in the second direction, each extends in the third direction, and separate, in the second direction, at least an interconnect layer provided at a position farthest from the source line among the plurality of interconnect layers. The plurality of memory pillars include a first memory pillar, a second memory pillar, a third memory pillar, a fourth memory pillar, and a fifth memory pillar arranged side by side in the third direction while alternately changing positions in the second direction in a first region between two first members adjacent in the third direction among the plurality of first members. The plurality of first contact plugs include a third contact plug provided on the first memory pillar, a fourth contact plug provided on the second memory pillar, a fifth contact plug provided on the third memory pillar, a sixth contact plug provided on the fourth memory pillar, and a seventh contact plug provided on the fifth memory pillar. A first shift amount obtained by shifting the third contact plug in the second direction with respect to the first memory pillar, a second shift amount obtained by shifting the fourth contact plug in the second direction with respect to the second memory pillar, a third shift amount obtained by shifting the fifth contact plug in the second direction with respect to the third memory pillar, a fourth shift amount obtained by shifting the sixth contact plug in the second direction with respect to the fourth memory pillar, and a fifth shift amount obtained by shifting the seventh contact plug in the second direction with respect to the fifth memory pillar are different from each other.

Hereinafter, embodiments will be described with reference to the drawings. Note that, in the following description, components having the same function and configuration are denoted by the same reference numerals. In addition, in a case where a plurality of components having a common reference sign is distinguished, the common reference sign is added with a suffix to be distinguished. Note that, in a case where a plurality of components does not need to be particularly distinguished, only common reference numerals are attached to the plurality of components, and no suffixes are attached thereto. Here, the suffix is not limited to a subscript or a superscript, and includes, for example, a lowercase alphabet added to the end of the reference sign, an index meaning an array, and the like.

A semiconductor memory device according to an embodiment will be described. Hereinafter, a three-dimensional stacked NAND flash memory in which memory cell transistors are three-dimensionally stacked on a semiconductor substrate will be described as an example of the semiconductor memory device.

### 1. Overall Configuration of Semiconductor Memory Device

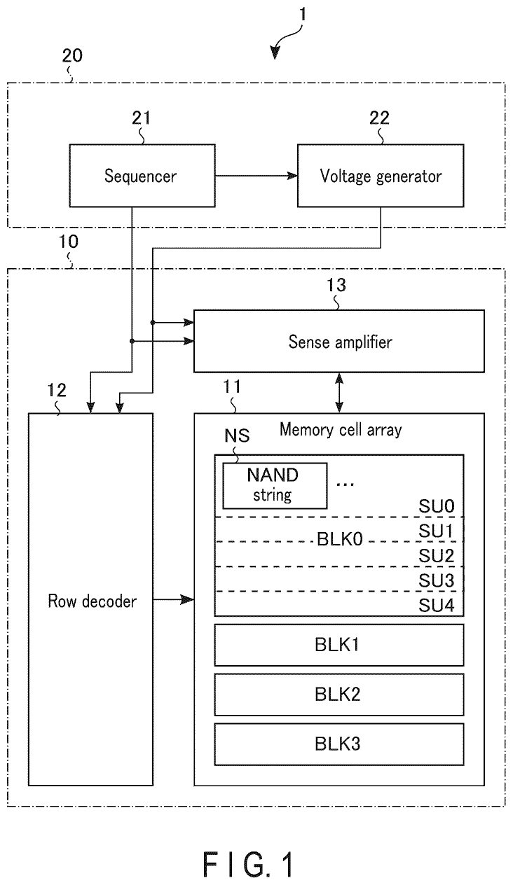

First, an example of the overall configuration of a semiconductor memory device 1 will be described with reference to FIG. 1. FIG. 1 is a block diagram illustrating the overall configuration of the semiconductor memory device 1. Note that some of couplings between respective components are indicated by arrow lines in FIG. 1. However, couplings between the constituent elements are not limited thereto.

As illustrated in FIG. 1, a semiconductor memory device 1 includes a memory core unit 10 and a peripheral circuit unit 20.

The memory core unit 10 includes a memory cell array 11, a row decoder 12, and a sense amplifier 13.

The memory cell array 11 is a region in which nonvolatile memory cell transistors (hereinafter, also referred to as a “memory cell”) are three-dimensionally arranged. The memory cell array 11 includes a plurality of blocks BLK. In the example illustrated in FIG. 1, the memory cell array 11 includes blocks BLK0 to BLK3. The block BLK is, for example, a set of a plurality of memory cells from which data is collectively erased. The block BLK includes a plurality of memory cells associated with a row and a column. Each block BLK includes a plurality of string units SU. In the example shown in FIG. 1, the block BLK includes five string units SU0, SU1, SU2, SU3, and SU4. The string unit SU includes, for example, a set of a plurality of NAND strings NS collectively selected in a write operation or a read operation. The NAND string NS includes a set of a plurality of memory cells coupled in series. Note that the number of blocks BLK in the memory cell array 11 and the number of string units SU in the block BLK are arbitrary. Details of the memory cell array 11 will be described later.

The row decoder 12 is a circuit that decodes a row address. The row decoder 12 receives information regarding a row address input from an external controller (not illustrated). The row decoder 12 selects interconnects (word lines and selection gate lines) in the row direction of the memory cell array 11 based on a decoding result of the information regarding the row address. The row decoder 12 supplies voltages to the selected interconnects in the row direction.

The sense amplifier 13 is a circuit that writes and reads data. In the read operation, the sense amplifier 13 reads data from memory cells of any block BLK. In addition, the sense amplifier 13 supplies voltages based on write data to the memory cell array 11 in the write operation.

The peripheral circuit unit 20 includes a sequencer 21 and a voltage generator 22.

The sequencer 21 controls the entire operation of the semiconductor memory device 1. More specifically, the sequencer 21 controls the voltage generator 22, the row decoder 12, the sense amplifier 13, and the like during the write operation, the read operation, and the erase operation.

The voltage generator 22 generates voltages used for the write operation, the read operation, and the erase operation, and supplies the voltages to the row decoder 12, the sense amplifier 13, and the like.

### 2. Circuit Configuration of Memory Cell Array

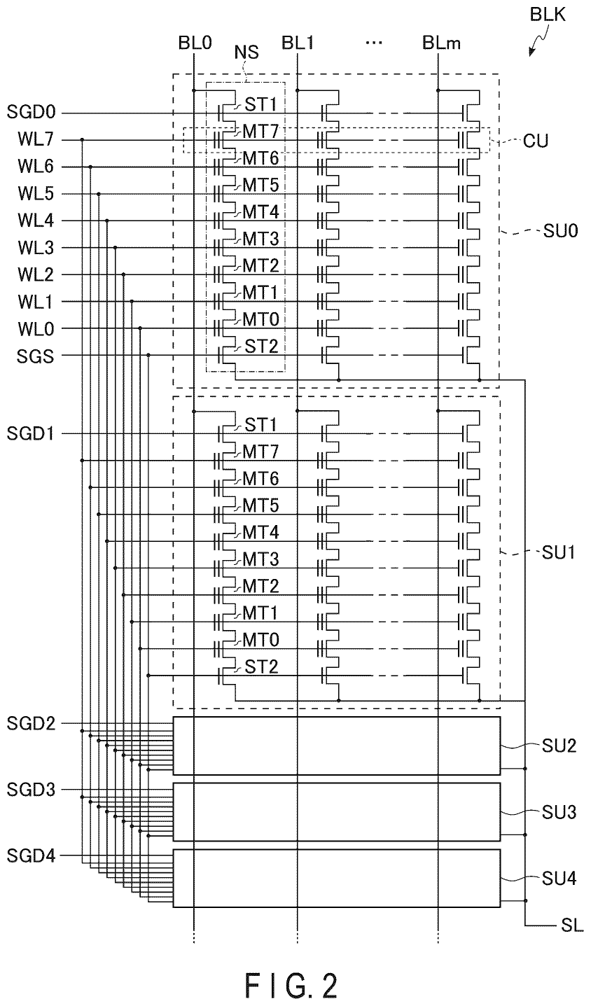

Next, an example of a circuit configuration of the memory cell array 11 will be described with reference to FIG. 2. FIG. 2 is a circuit diagram illustrating an example of a circuit configuration of the memory cell array 11. The example illustrated in FIG. 2 illustrates a circuit diagram of one block BLK.

As shown in FIG. 2, the block BLK includes a plurality of string units SU. In the example shown in FIG. 2, the block BLK includes five string units SU0 to SU4. The string unit SU is a set of a plurality of NAND strings NS.

The NAND string NS is a set of a plurality of memory cells MC coupled in series. Each of the plurality of NAND strings NS in the string unit SU is coupled to any of bit lines BL0 to BLm (m is an integer of 1 or more). Each NAND string NS includes a plurality of memory cells MC and selection transistors ST1 and ST2. In the example illustrated in FIG. 2, the NAND string NS includes eight memory cells MC0 to MC7.

The memory cell MC is a memory element that stores data in a nonvolatile manner. The memory cell MC includes a control gate and a charge storage film. The memory cell MC may be a floating gate (FG) type or a metal-oxide-nitride-oxide-silicon (MONOS) type. In the FG type, a conductor is used for the charge storage film. In the MONOS type, an insulating layer is used for the charge storage film. Hereinafter, a case where the memory cell MC is of the MONOS type will be described.

The selection transistors ST1 and ST2 are switching elements. The selection transistors ST1 and ST2 are used to select the string unit SU during various operations, respectively.

The current paths of the selection transistor ST2, the memory cells MC0 to MC7, and the selection transistor ST1 in the NAND string NS are coupled in series. A drain of the selection transistor ST1 is coupled to the bit line BL. A source of the selection transistor ST2 is coupled to a source line SL.

Control gates of the plurality of memory cells MC0 to MC7 of the same block BLK are commonly coupled to the word lines WL0 to WL7, respectively. More specifically, for example, each of the string units SU0 to SU4 includes a plurality of memory cells MC0. The control gates of the plurality of memory cells MC0 in the block BLK are coupled to one word line WL0. The same applies to the memory cells MC1 to MC7. For example, the control gates of the plurality of memory cells MC1 in the block BLK are coupled to one word line WL1.

Gates of the plurality of selection transistors ST1 in each string unit SU are commonly coupled to one select gate line SGD. More specifically, gates of the plurality of selection transistors ST1 in the string unit SU0 are commonly coupled to a select gate line SGD0. Gates of the plurality of selection transistors ST1 in the string unit SU1 are commonly coupled to a select gate line SGD1. Gates of the plurality of selection transistors ST1 in the string unit SU2 are commonly coupled to a select gate line SGD2. Gates of the plurality of selection transistors ST1 in the string unit SU3 are commonly coupled to a select gate line SGD3. Gates of the plurality of selection transistors ST1 in the string unit SU4 are commonly coupled to a select gate line SGD4.

Gates of the plurality of selection transistors ST2 in the block BLK are commonly coupled to a select gate line SGS.

The word lines WL0 to WL7, the select gate lines SGD0 to SGD3, and the select gate line SGS are coupled to the row decoder 12.

The bit line BL is commonly coupled to one NAND string NS of each of the plurality of string units SU of each block BLK. For example, the bit line BL0 is coupled to one NAND string NS in the string unit SU0, one NAND string NS in the string unit SU1, one NAND string NS in the string unit SU2, one NAND string NS in the string unit SU3, and one NAND string NS in the string unit SU4. The same applies to the bit lines BL1 to BLm. Each bit line BL is coupled to the sense amplifier 13.

The source line SL is shared among the plurality of blocks BLK, for example.

A set of the plurality of memory cells MC coupled to one word line WL in one string unit SU is referred to as, for example, “cell unit CU”. In other words, the cell unit CU is a set of a plurality of memory cells MC collectively selected in the write operation or the read operation. A page is a unit of data that is collectively written (or collectively read) to the cell unit CU. For example, in a case where the memory cell MC stores 1-bit data, a storage capacity of the cell unit CU is one page. That is, the cell unit CU stores one-page data. The cell unit CU may have a storage capacity of two or more pages based on the number of bits of data stored in the memory cell MC. The memory cell MC may be a single level cell (SLC) that stores one-bit data or a multi level cell (MLC) that stores two-bit data. In addition, the memory cell MC may be a triple level cell (TLC) that stores three-bit data, a quad level cell (QLC) that stores four-bit data, or a penta level cell (PLC) that stores five-bit data.

### 3. Structure of Memory Cell Array

Next, an example of a structure of the memory cell array 11 will be described. In the drawings referred to below, the X direction corresponds to the extending direction of the word line WL. The Y direction corresponds to the extending direction of the bit line BL. The Z direction corresponds to a direction intersecting the X direction and the Y direction. Note that, in the plan view, hatching is appropriately added in order to make the drawing easy to see. The hatching added to the plan view is not necessarily related to a material or a characteristic of the component to which the hatching is added. In the cross-sectional view, illustration of the configuration can be appropriately omitted in order to make the view easy to see.

### 3.1 Overview of Planar Layout

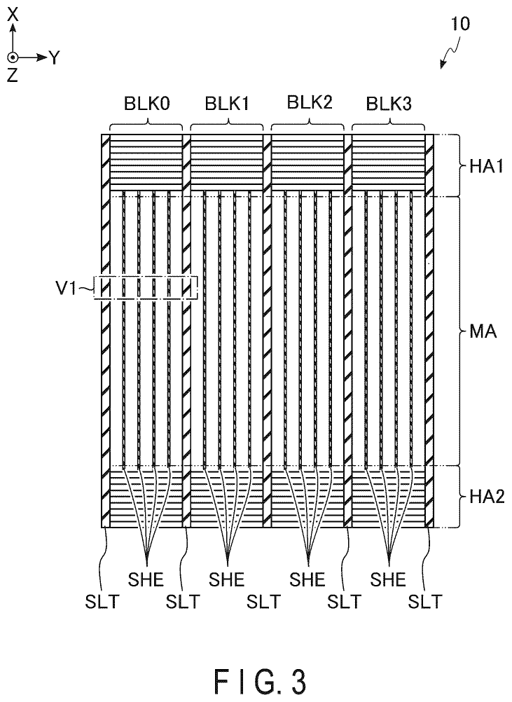

First, an example of a planar layout of the memory cell array 11 will be described with reference to FIG. 3. FIG. 3 is a plan view illustrating an example of the memory cell array 11. The example illustrated in FIG. 3 illustrates regions corresponding to the four blocks BLK0 to BLK3.

As illustrated in FIG. 3, the planar layout of the memory cell array 11 is divided into, for example, a memory area MA and hookup areas HA1 and HA2 in the X direction. In addition, the memory cell array 11 includes a plurality of members SLT and SHE.

The memory area MA is disposed between the hookup area HA1 and the hookup area HA2. The memory area MA is a region including a plurality of NAND strings NS. Each of the hookup areas HA1 and HA2 is a region used for coupling between a stacked interconnects (for example, the select gate line SGS, the word lines WL0 to WL7, and the select gate line SGD) stacked in the Z direction and the row decoder 12.

Each of the plurality of members SLT extends in the X direction and is arranged in the Y direction. Each member SLT crosses the memory area MA and the hookup areas HA1 and HA2 in the X direction in a boundary region between the adjacent blocks BLK. Each member SLT may have, for example, a structure in which an insulator and a plate-like contact is embedded. Each member SLT divides the stacked interconnects adjacent to each other with the member SLT interposed therebetween.

The plurality of members SHE extends along the X direction and is arranged in the Y direction. In this example, four members SHE are disposed between the adjacent members SLT. Each member SHE crosses the memory area MA in the X direction. Both ends of each member SHE are included in the hookup areas HA1 and HA2, respectively. Each member SHE has, for example, a structure in which an insulator is embedded. Each member SHE divides the adjacent select gate lines SGD through the member SHE. Therefore, the select gate line SGD is divided for each string unit SU by the members SLT and SHE.

Each of the regions divided by the member SLT corresponds to one block BLK. Each of the regions divided by the members SLT and SHE corresponds to one string unit SU.

The planar layout of the memory cell array 11 is not limited to the layout described above. For example, the number of members SHE disposed between the adjacent members SLT can be designed to be any number. The number of string units SU formed between the adjacent members SLT can be changed based on the number of members SHE arranged between the adjacent members SLT.

### 3.2 Planar Layout of Memory Area

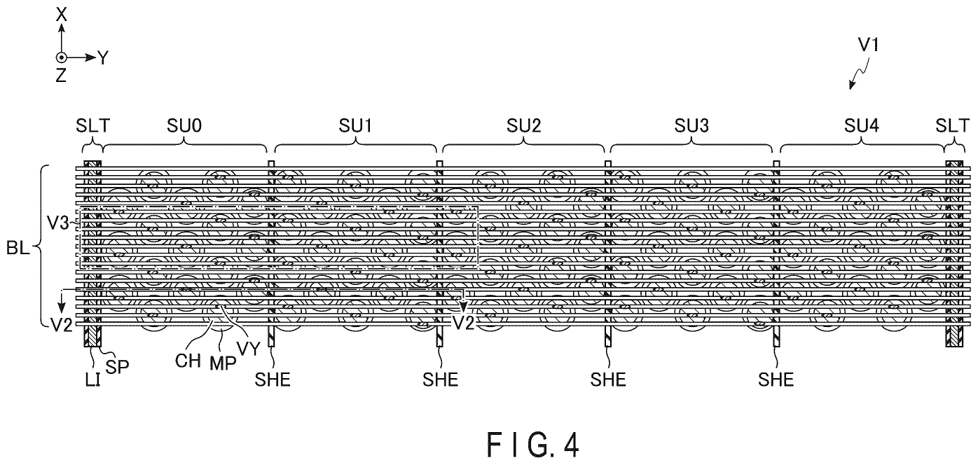

Next, details of the planar layout in the memory area MA will be described with reference to FIG. 4. FIG. 4 is an enlarged plan view of a region V1 in FIG. 3. FIG. 4 illustrates a region including one block BLK (that is, the string units SU0 to SU4) and two members SLT sandwiching the block BLK.

As illustrated in FIG. 4, in the memory area MA, the memory cell array 11 includes a plurality of memory pillars MP, a plurality of contact plugs CH, a plurality of contact plugs VY, and a plurality of bit lines BL. Each member SLT includes a conductor LI and a spacer SP.

Each of the memory pillars MP functions as, for example, one NAND string NS. The plurality of memory pillars MP is arranged in 25 rows in a staggered manner in the X direction, for example, in a region between two adjacent members SLT. In other words, the plurality of memory pillars MP is arranged in 25 rows in a staggered manner in the X direction in the region corresponding to one block BLK. In other words, the plurality of memory pillars MP is arranged in five rows in a staggered manner in the X direction in a region between adjacent two members SLT or members SHE extending in the X direction, that is, in a region corresponding to one string unit SU. For example, in a case of being counted from the left side of the paper surface of FIG. 4, the members SHE are provided between the memory pillars MP of a fifth row and the memory pillars MP of a sixth row, between the memory pillars MP of a 10th row and the memory pillars MP of an 11th row, between the memory pillars MP of a 15th row and the memory pillars MP of a 16th row, and between the memory pillars MP of a 20th row and the memory pillars MP of a 21th row.

The plurality of bit lines BL extends in the Y direction and is arranged in the X direction. The bit line BL is disposed above the memory pillar MP. Each bit line BL is arranged so as to overlap at least one memory pillar MP for each string unit SU in a plan view seen from the Z direction. In the example shown in FIG. 4, five bit lines BL are arranged so as to overlap any of five rows of memory pillars MP arranged in a staggered manner in one string unit SU.

A contact plug CH is provided on each memory pillar MP. In the present embodiment, the contact plug CH is arranged at a position where the center axis extending in the Z direction of the contact plug CH is shifted in the X direction from the center axis extending in the Z direction of the memory pillar MP. That is, the position of the center axis of the contact plug CH and the position of the center axis of the memory pillar MP are different in plan view. In the following description, an arrangement in which the contact plug CH is shifted in the X direction with respect to the memory pillar MP is referred to as a “CH shift”. The shift amount of the CH shift is referred to as a “CH shift amount”. For example, in one string unit SU, CH shift amounts of five contact plugs CH corresponding to five memory pillars MP arranged in five rows in a staggered manner in the X direction are different from each other. Details of the CH shift amount will be described later.

A contact plug VY is provided on the contact plug CH. The memory pillar MP is electrically coupled to any one of the bit lines BL through the contact plug CH and the contact plug VY. The contact plug VY is disposed so as to overlap with the coupled bit line BL in plan view. Therefore, the position of the center axis of the contact plug VY and the position of the center axis of the contact plug CH are different in plan view.

The number and arrangement of the memory pillars MP, the contact plugs CH, the contact plugs VY, the members SHE, and the like between the adjacent members SLT are not limited to the configuration described with reference to FIG. 4, and can be appropriately changed.

The conductor LI is a conductor extending in the XZ plane provided in the member SLT. The spacer SP is an insulator provided on a side surface of the conductor LI. In other words, the conductor LI is surrounded by the spacer SP in plan view. The conductor LI is electrically coupled to the source line SL. The conductor LI may be eliminated. In this case, the inside of the member SLT is filled with an insulator.

### 3.3 Cross-Sectional Structure of Memory Area

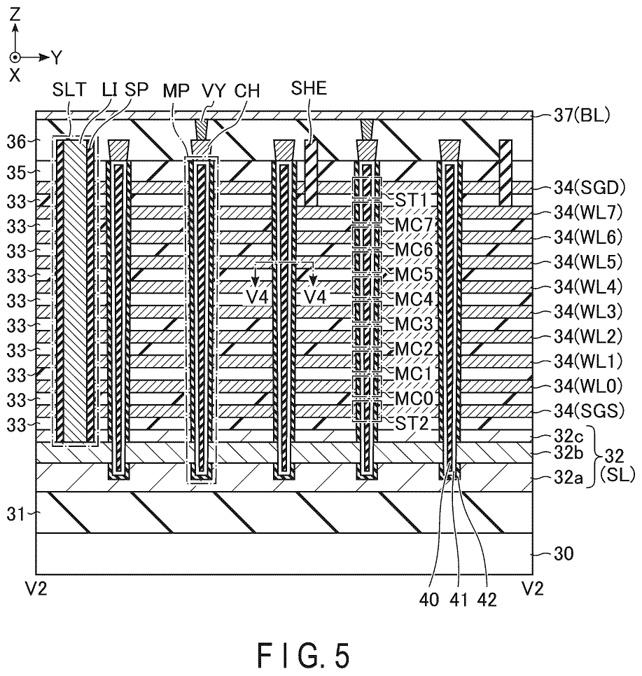

Next, an example of a cross-sectional structure of the memory area MA will be described with reference to FIG. 5. FIG. 5 is a cross-sectional view of the memory area MA taken along a line V2-V2 illustrated in FIG. 4.

As illustrated in FIG. 5, the memory cell array 11 includes a semiconductor substrate 30, insulating layers 31, 33, 35, and 36, a semiconductor layer 32, and interconnect layers 34 and 37.

The semiconductor substrate 30 is, for example, a P-type semiconductor. The insulating layer 31 is provided on the semiconductor substrate 30. The insulating layer 31 includes, for example, silicon oxide (SiO). The semiconductor substrate 30 and the insulating layer 31 may include a circuit (not illustrated). The circuits included in the semiconductor substrate 30 and the insulating layer 31 correspond to the row decoder 12, the sense amplifier 13, and the like. The semiconductor layer 32 is provided on the insulating layer 31.

The semiconductor layer 32 is, for example, a plate-like semiconductor extending along the XY plane. The semiconductor layer 32 is used as the source line SL. The semiconductor layer 32 includes, for example, three semiconductor layers 32a, 32b, and 32c. The semiconductor layer 32a is provided on the insulating layer 31. The semiconductor layer 32b is provided on the semiconductor layer 32a. The semiconductor layer 32c is provided on the semiconductor layer 32b. The semiconductor layer 32b is formed, for example, by replacing a sacrificial layer provided between the semiconductor layer 32a and the semiconductor layer 32c. The semiconductor layers 32a to 32c include, for example, silicon. In addition, the semiconductor layers 32a to 32c include, for example, phosphorus (P) as an impurity of the semiconductor.

For example, 10 insulating layers 33 and 10 interconnect layers 34 are alternately stacked one by one on the semiconductor layer 32. In the example illustrated in FIG. 5, the 10 interconnect layers 34 function as the select gate line SGS, the word lines WL0 to WL7, and the select gate line SGD in order from the side closer to the semiconductor layer 32. A plurality of interconnect layers 34 functioning as the select gate lines SGS or SGD may be provided. The insulating layer 33 includes, for example, silicon oxide. As the conductive material of the interconnect layer 34, for example, a stacked structure of titanium nitride (TiN)/tungsten (W) is used. In this case, titanium nitride is formed so as to cover tungsten. Titanium nitride has a function as a barrier layer for suppressing oxidation of tungsten or an adhesion layer for improving adhesion of tungsten in a case where tungsten is deposited by, for example, chemical vapor deposition (CVD).

In addition, the interconnect layer 34 may include a high dielectric constant material such as aluminum oxide (AlO). In this case, the high dielectric constant material is formed so as to cover the conductive material. For example, in each of the interconnect layers 34, a high dielectric constant material is provided so as to be in contact with the insulating layers 33 or 35 provided above and below the interconnect layer 34 and the side surfaces of the memory pillars MP. Then, titanium nitride is provided so as to be in contact with the high dielectric constant material. Then, tungsten is provided so as to be in contact with titanium nitride and fill the inside of the interconnect layer 34. For example, in a case where aluminum oxide is used as the high dielectric constant material, the memory cell MC is also referred to as a metal-aluminum-nitride-oxide-silicon (MANOS) type.

The insulating layer 35 is provided on the uppermost interconnect layer 34 functioning as the select gate line SGD. In other words, the insulating layer 35 is provided on the interconnect layer 34 provided at the position farthest from the semiconductor layer 32. The insulating layer 35 includes, for example, silicon oxide.

A plurality of memory pillars MP is provided in the memory cell array 11. For example, the memory pillar MP has a substantially cylindrical shape extending in the Z direction. The memory pillar MP penetrates the 10 interconnect layers 34. The bottom surface of the memory pillar MP reaches the semiconductor layer 32. Note that the memory pillar MP may have a structure in which a plurality of pillars is coupled in the Z direction.

Each memory pillar MP includes, for example, a core film 40, a semiconductor film 41, and a stacked film 42. The core film 40 extends in the Z direction. For example, the upper end of the core film 40 is located above the interconnect layer 34, and the lower end of the core film 40 is located in the same layer as the semiconductor layer 32. The semiconductor film 41 extends in the Z direction and covers the periphery of the core film 40. A side surface of the semiconductor film 41 is in contact with the semiconductor layer 32b. The stacked film 42 covers the side surface and a bottom surface of the semiconductor film 41 except for a portion where the semiconductor film 41 and the semiconductor layer 32b are in contact with each other. The core film 40 includes an insulator such as silicon oxide. The semiconductor film 41 includes, for example, silicon. The stacked film 42 includes a charge storage film. Details of the configuration of the stacked film 42 will be described later.

The memory pillar MP and the interconnect layers 34 functioning as the word lines WL0 to WL7 are combined to form the memory cells MC0 to MC7. Similarly, the memory pillar MP and the interconnect layer 34 functioning as the select gate line SGD are combined to form the selection transistor ST1. The memory pillar MP and the interconnect layer 34 functioning as the select gate line SGS are combined to form the selection transistor ST2.

Above the insulating layer 35, the interconnect layer 37 is provided through the insulating layer 36. The insulating layer 36 includes, for example, silicon oxide. The interconnect layer 37 is formed in a line shape extending in the Y direction, for example, and functions as the bit line BL. In a region (not illustrated), the plurality of interconnect layers 37 is arranged side by side in the X direction. The interconnect layer 37 includes, for example, copper (Cu) as a conductive material.

The contact plug CH is provided on the semiconductor film 41 of each memory pillar MP. The contact plug CH has, for example, a substantially cylindrical shape extending in the Z direction. More specifically, the contact plug CH has, for example, a truncated cone shape in which an area of the upper surface is larger than an area of the bottom surface. The contact plug CH includes, for example, copper as a conductive material.

The contact plug VY is provided on each contact plug CH. The contact plug VY has, for example, a columnar shape extending in the Z direction. More specifically, the contact plug VY has, for example, an elliptical frustum shape in which an area of the upper surface is larger than an area of the bottom surface. In the example illustrated in FIG. 5, a plurality of contact plugs VY commonly coupled to one interconnect layer 37 is displayed in each of cross-sectional regions of the string units SU divided by the members SLT and SHE. The memory pillar MP on which the contact plug VY is not displayed is coupled to a different interconnect layer 37 through the contact plug VY (not illustrated) in a region (not illustrated).

The member SLT separates the 10 interconnect layers 34. The conductor LI in the member SLT is provided along the spacer SP. An upper end of the conductor LI is located in a layer between the interconnect layer 34 and the interconnect layer 37. A lower end of the conductor LI is in contact with the semiconductor layer 32b. The spacer SP is provided between the conductor LI and the interconnect layers 34. The conductor LI and the interconnect layers 34 are separated and insulated by the spacer SP.

The member SHE separates the interconnect layer 34 functioning as the select gate line SGD. In other words, the member SHE separates the interconnect layer 34 provided at least at a position farthest from the semiconductor layer 32 among the plurality of interconnect layers 34. An upper end of the member SHE is located in a layer between the interconnect layer 34 and the interconnect layer 37. A lower end of the member SHE is located in a layer between the interconnect layer 34 functioning as the select gate line SGD and the interconnect layer 34 functioning as the word line WL. The lower end of the member SHE becomes deeper according to the number of interconnect layers 34 functioning as the select gate lines SGD. The member SHE includes, for example, an insulator such as silicon oxide. The upper end of the member SHE and the upper end of the member SLT may be aligned or may not be aligned. In addition, the upper end of the member SHE and the upper end of the memory pillar MP may be aligned or may not be aligned.

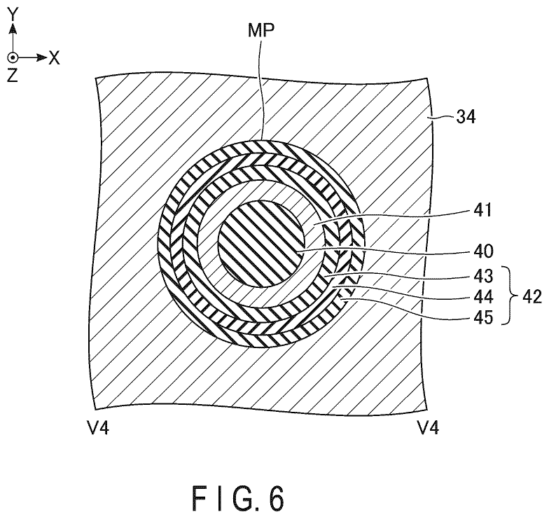

Next, an example of a cross-sectional structure of the memory pillar MP will be described with reference to FIG. 6. FIG. 6 is a cross-sectional view taken along a line V4-V4 in FIG. 5. More specifically, FIG. 6 illustrates a cross-sectional structure of the memory pillar MP in a layer parallel to an XY plane and including the interconnect layer 34.

As illustrated in FIG. 6, the stacked film 42 includes, for example, a tunnel insulating film 43, a charge storage film 44, and a block insulating film 45.

In the cross section including the interconnect layer 34, the core film 40 is provided, for example, at the central portion of the memory pillar MP. The semiconductor film 41 surrounds the side surface of the core film 40. The tunnel insulating film 43 surrounds the side surface of the semiconductor film 41. The charge storage film 44 surrounds the side surface of the tunnel insulating film 43. The block insulating film 45 surrounds the side surface of the charge storage film 44. The interconnect layer 34 surrounds the side surface of the block insulating film 45.

The semiconductor film 41 is used as a channel (current path) of the memory cells MC0 to MC7 and the selection transistors ST1 and ST2. Each of the tunnel insulating film 43 and the block insulating film 45 includes, for example, silicon oxide. The charge storage film 44 has a function of accumulating charges, and includes, for example, silicon nitride. As a result, each memory pillar MP can function as one NAND string NS.

### 4. Arrangement of Contact Plug CH

Next, details of the arrangement of the contact plug CH will be described.

### 4.1 CH Shift

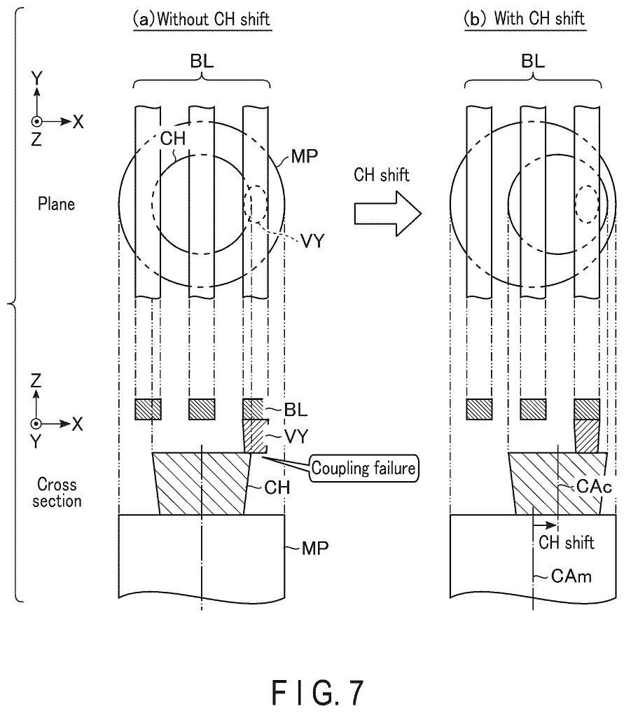

First, the CH shift will be described with reference to FIG. 7. FIG. 7 is a diagram illustrating an example of a positional relationship among the memory pillar MP, the contact plugs CH and VY, and the bit lines BL in the presence or absence of the CH shift. FIG. 7 illustrates a plane and a cross section focusing on one memory pillar MP.

As illustrated in FIG. 7, a plurality of bit lines BL is arranged above one memory pillar MP. The memory pillar MP is electrically coupled to any one of the plurality of bit lines BL through the contact plugs CH and VY.

In the example illustrated in FIG. 7, the memory pillar MP is electrically coupled to the bit line BL arranged on the right side of the paper surface among the three bit lines BL provided above the memory pillar MP. The contact plug VY is disposed below the coupled bit line BL. Therefore, the arrangement of the contact plug VY in the X direction is determined according to the arrangement of the coupled bit lines BL. Therefore, the contact plug VY can be arranged at a position shifted in the X direction from the center of the memory pillar MP.

FIG. 7(a) illustrates a case where the memory pillar MP and the contact plug CH are arranged on concentric axes, that is, a case where there is no CH shift. In this case, as the distance from the center of the memory pillar MP to the contact plug VY in the X direction increases, the contact area between the upper surface of the contact plug CH and the lower surface of the contact plug VY decreases. In other words, in a case where the shift amount of the contact plug VY increases, the contact plug VY is tripped off. As a result, a coupling failure (contact failure) occurs between the contact plug CH and the contact plug VY.

On the other hand, FIG. 7(b) illustrates a case where the memory pillar MP and the contact plug CH are not arranged on concentric axes, that is, a case where there is a CH shift. For example, a center axis CAc of the contact plug CH is shifted from the center axis CAm of the memory pillar MP toward the contact plug VY. As a result, even if the shift amount of the contact plug VY increases, it is possible to suppress a decrease in the contact area between the upper surface of the contact plug CH and the lower surface of the contact plug VY. As a result, a coupling failure (contact failure) between the contact plug CH and the contact plug VY can be suppressed by the CH shift.

### 4.2 Specific Example of CH Shift Amount

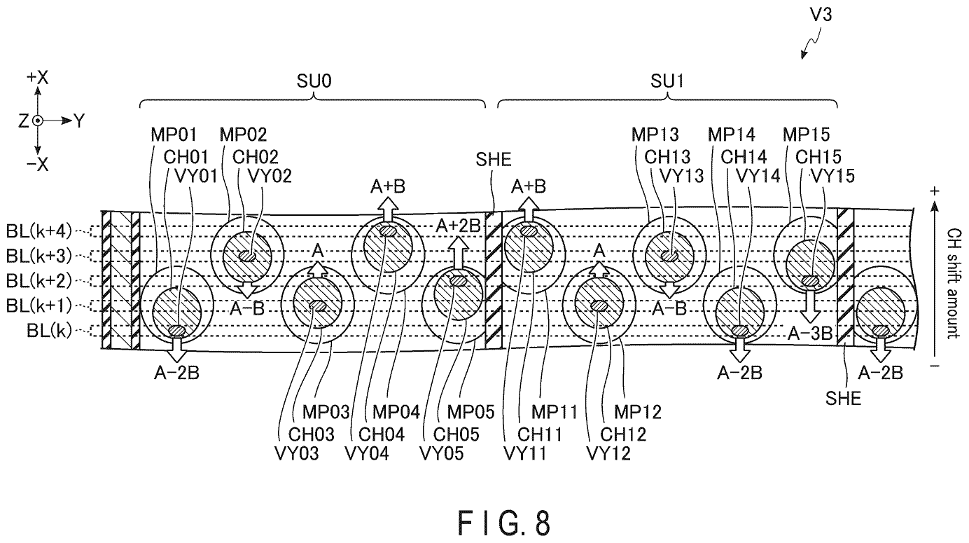

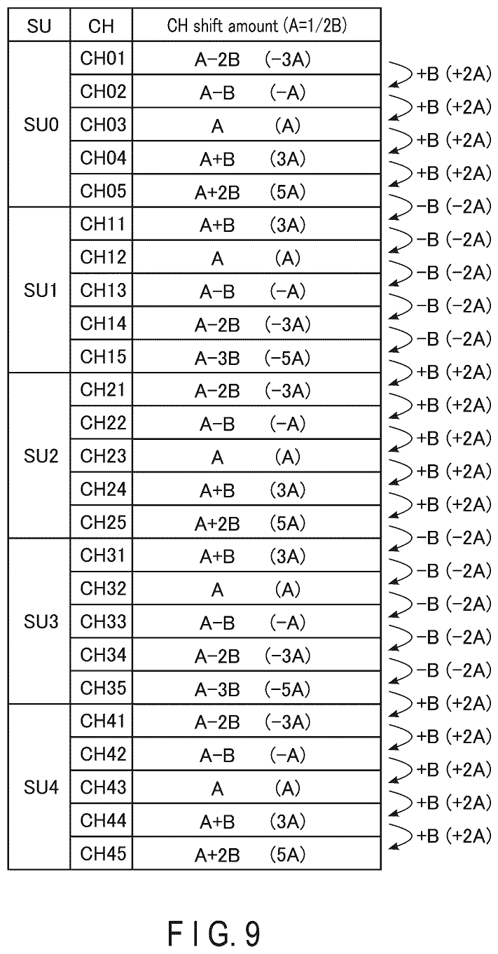

Next, a specific example of the CH shift amount of the contact plug CH will be described with reference to FIGS. 8 and 9. FIG. 8 is an enlarged plan view of a region V3 in FIG. 4. FIG. 9 is a table illustrating an example of the CH shift amount in one block BLK. In FIG. 8, in each of the two string units SU0 and SU1, five memory pillars MP arranged in five rows in a staggered manner in the X direction and the contact plugs CH and VY and the bit lines BL corresponding thereto are extracted and illustrated. In the description using FIG. 8, a direction toward the upper side of the paper surface is referred to as a +X direction, and a direction toward the lower side of the paper surface is referred to as a −X direction. Further, the +X direction is defined as a +(plus) direction of the CH shift amount, and the −X direction is defined as a − (minus) direction of the CH shift amount.

As illustrated in FIG. 8, for example, in the string unit SU0, five memory pillars MP arranged in five rows in a staggered manner in the X direction are referred to as memory pillars MP01, MP02, MP03, MP04, and MP05 in order from the left side of the paper surface. The contact plugs CH arranged on the memory pillars MP01, MP02, MP03, MP04, and MP05 are referred to as contact plugs CH01, CH02, CH03, CH04, and CH05, respectively. Further, the contact plugs VY arranged on the contact plugs CH01, CH02, CH03, CH04, and CH05 are referred to as contact plugs VY01, VY02, VY03, VY04, and VY05, respectively.

Similarly, in the string unit SU1, five memory pillars MP arranged in five rows in a staggered manner in the X direction are referred to as memory pillars MP11, MP12, MP13, MP14, and MP15 in order from the left side of the paper surface. The contact plugs CH arranged on the memory pillars MP11, MP12, MP13, MP14, and MP15 are referred to as contact plugs CH11, CH12, CH13, CH14, and CH15, respectively. Further, the contact plugs VY arranged on the contact plugs CH11, CH12, CH13, CH14, and CH15 are referred to as contact plugs VY11, VY12, VY13, VY14, and VY15, respectively.

Note that, in the description of FIG. 8, in a case where any of the string units SU0 and SU1 is not limited, the string units are simply referred to as the memory pillars MP1 to MP5, the contact plugs CH1 to CH5, and the contact plugs VY1 to VY5.

Further, in each string unit SU, the five bit lines BL arranged above the five memory pillars MP1 to M5 are sequentially set as bit lines BL(k), BL(k+1), BL(k+2), BL(k+3), and BL(k+4) in the +X direction (k is an integer of 0 or more and (m−4) or less). Further, a CH shift amount of the entire contact plug CH is set as a variable A, and a difference in CH shift amount between two contact plugs CH adjacent in the Y direction is set as a variable B.

First, the string unit SU0 will be described.

The memory pillars MP01 to MP05 are arranged in five rows in a staggered manner in the Y direction. The positions of the memory pillars MP01, MP03, and MP05 in the X direction are the same. Further, the positions of the memory pillars MP02 and MP04 in the X direction are the same. The memory pillars MP01 to MP05 are arranged side by side in the Y direction while alternately changing the positions in the X direction.

For example, the memory pillar MP01 is coupled to the bit line BL(k). That is, the contact plug VY01 is disposed below the bit line BL(k). The contact plug VY01 is arranged at a position shifted in the −X direction from the center of the memory pillar MP01. Therefore, the CH shift of the contact plug CH01 is directed in the −X direction from the center of the memory pillar MP01. For example, the CH shift amount of the contact plug CH01 at this time is A−2B.

For example, the memory pillar MP02 is coupled to the bit line BL(k+3). That is, the contact plug VY02 is disposed under the bit line BL(k+3). For example, two memory pillars MP adjacent to each other in the Y direction are coupled to two different bit lines BL with one or more bit lines BL interposed therebetween. Specifically, for example, the bit line BL coupled to the memory pillar MP02 is selected from the bit lines BL other than the bit line BL(k+1). A distance from the center of the memory pillar MP02 to the contact plug VY02 is shorter than a distance from the center of the memory pillar MP01 to the contact plug VY01. Therefore, the CH shift amount of the contact plug CH02 is +B added to the CH shift amount (A−2B) of the contact plugs CH01 adjacent in the Y direction to be A−B.

For example, the memory pillar MP03 is coupled to the bit line BL(k+1). That is, the contact plug VY03 is disposed under the bit line BL(k+1). The CH shift amount of the contact plug CH03 is A obtained by adding +B to the CH shift amount (A−B) of the contact plugs CH02 adjacent in the Y direction.

For example, the memory pillar MP04 is coupled to the bit line BL(k+4). That is, the contact plug VY04 is disposed under the bit line BL(k+4). The contact plug VY04 is arranged at a position shifted in the +X direction from the center of the memory pillar MP04. The CH shift amount of the contact plug CH04 is A+B obtained by adding +B to the CH shift amount (A) of the contact plug CH03 adjacent in the Y direction.

For example, the memory pillar MP05 is coupled to the bit line BL(k+2). That is, the contact plug VY05 is disposed under the bit line BL(k+2). The contact plug VY05 is arranged at a position shifted in the +X direction from the center of the memory pillar MP05. The CH shift amount of the contact plug CH05 is A+2B obtained by adding +B to the CH shift amount (A+B) of the contact plugs CH04 adjacent in the Y direction.

Next, the string unit SU1 will be described.

For example, the memory pillar MP11 is coupled to the bit line BL(k+4) similarly to the memory pillar MP04. That is, the contact plug VY11 is disposed under the bit line BL(k+4). The CH shift amount of the contact plug CH11 is added by −B to the CH shift amount (A+2B) of the contact plug CH05 adjacent in the Y direction with the member SHE interposed therebetween, and is set to A+B similarly to the contact plug CH04.

For example, the memory pillar MP12 is coupled to the bit line BL(k+1) similarly to the memory pillar MP03. That is, the contact plug VY12 is disposed under the bit line BL(k+1). The CH shift amount of the contact plug CH12 is added by −B to the CH shift amount (A+B) of the contact plug CH11 adjacent in the Y direction, and is set to A similarly to the contact plug CH03.

For example, the memory pillar MP13 is coupled to the bit line BL(k+3) similarly to the memory pillar MP02. That is, the contact plug VY13 is disposed under the bit line BL(k+3). The CH shift amount of the contact plug CH13 is added by −B to the CH shift amount (A) of the contact plug CH12 adjacent in the Y direction, and is set to A−B similarly to the contact plug CH02.

For example, the memory pillar MP14 is coupled to the bit line BL(k) similarly to the memory pillar MP01. That is, the contact plug VY14 is disposed under the bit line BL(k). The CH shift amount of the contact plug CH14 is set to A−2B similarly to the contact plug CH01 by adding −B to the CH shift amount (A−B) of the contact plug CH13 adjacent in the Y direction.

For example, the memory pillar MP15 is coupled to the bit line BL(k+2). That is, the contact plug VY15 is disposed under the bit line BL(k+2). The contact plug VY15 is arranged at a position shifted in the −X direction from the center of the memory pillar MP5. The CH shift amount of the contact plug CH15 is set to A−2B by adding −B to the CH shift amount (A−3B) of the contact plugs CH14 adjacent in the Y direction.

Note that the CH shift amounts of the contact plugs CH corresponding to the plurality of memory pillars MP arranged side by side in the X direction (not illustrated) are the same. Specifically, for example, the CH shift amount of the plurality of contact plugs CH01 corresponding to the plurality of memory pillars MP01 arranged side by side in the X direction is A−2B.

Next, an example of the CH shift amount in one block BLK will be described with reference to FIG. 9. In FIG. 9, the CH shift amount in parentheses indicates the CH shift amount in a case where the variable A and the variable B have a relationship of A=1/2B using the variable A. Hereinafter, the contact plugs CH1 to CH5 in the string unit SU2 are referred to as CH21 to CH25. The contact plugs CH1 to CH5 in the string unit SU3 are referred to as CH31 to CH35. The contact plugs CH1 to CH5 in the string unit SU4 are referred to as CH41 to CH45.

As illustrated in FIG. 9, in the string unit SU0, the CH shift amount of each of the contact plugs CH01 to CH05 is A−2B, A−B, A, A+B, and A+2B as described with reference to FIG. 8. For example, in a case of A=1/2B, the CH shift amount of each of the contact plugs CH01 to CH05 can be expressed as −3A, −A, A, +3A, and +5A. The CH shift amount is added B by B in order from the contact plug CH01. That is, the amount of change (difference) in the CH shift amounts of the two contact plugs CH adjacent to each other in the Y direction is B (constant). In a case of A=1/2B, the CH shift amount is added by 2A in order from the contact plug CH01. That is, the amount of change in the CH shift amount of the two contact plugs CH adjacent to each other in the Y direction is 2A.

In the string unit SU1, the CH shift amount of each of the contact plugs CH11 to CH15 is A+B, A, A−B, A−2B, and A−3B as described with reference to FIG. 8. For example, in a case of A=1/2B, the CH shift amount of each of the contact plugs CH11 to CH15 is represented as 3A, A, −A, −3 A, or −5 A. In this case, the CH shift amount is added by −B (subtracted by B) in order from the contact plug CH11. Similarly to the string unit SU0, the amount of change in the CH shift amount of the two contact plugs CH adjacent in the Y direction is B (constant). In a case of A=1/2B, the CH shift amount is added by −2A (subtracted by 2A) in order from the contact plug CH11. That is, similarly to the string unit SU0, the amount of change in the CH shift amount of the two contact plugs CH adjacent in the Y direction is 2A.

In the string unit SU2, the CH shift amount of each of the contact plugs CH21 to CH25 is similar to that of the contact plugs CH01 to CH05.

In the string unit SU3, the CH shift amount of each of the contact plugs CH31 to CH35 is similar to that of the contact plugs CH11 to CH15.

In the string unit SU4, the CH shift amount of each of the contact plugs CH41 to CH45 is similar to that of the contact plugs CH01 to CH05.

In the example illustrated in FIG. 9, the maximum value of an absolute value of the CH shift amount is |A+2B| or |A−3B|. That is, in a case of A=1/2B, the maximum value of the absolute value of the CH shift amount is |5A|. These values are CH shift amounts of any of the contact plugs CH05, CH15, CH25, CH35, and CH45. The contact plugs CH05, CH15, CH25, CH35, and CH45 are disposed adjacent to the different members SHE. That is, the absolute value of the CH shift amount of the contact plug CH arranged adjacent to the member SHE becomes the maximum value.

### 4.3 Maximum Value of Shift Amount of Contact Plug CH and Maximum Value of Misalignment Amount of Contact Plug VY

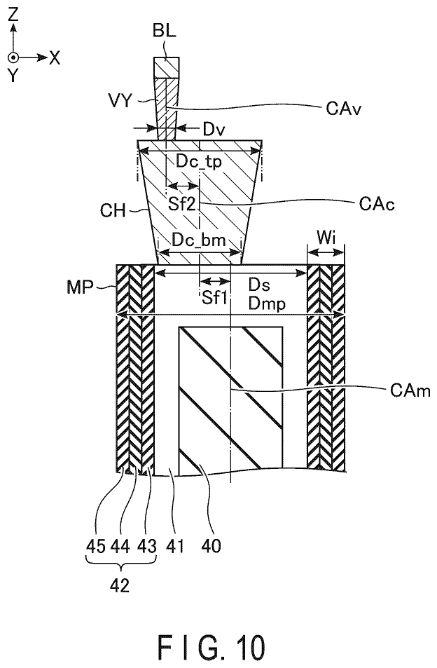

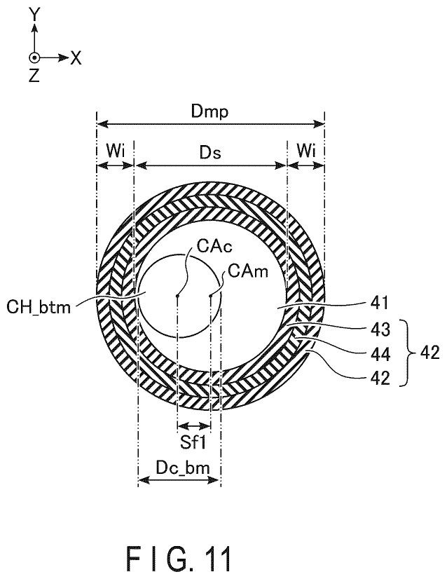

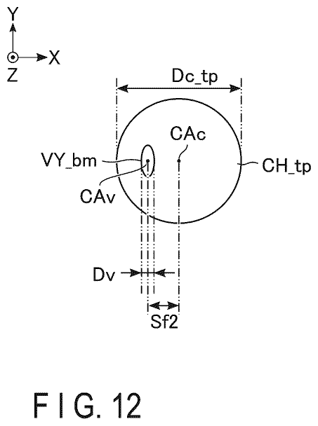

Next, an example of maximum value of the shift amount of the contact plug CH and the maximum value of the misalignment amount of the contact plug VY will be described with reference to FIGS. 10 to 12. FIG. 10 is a cross-sectional view illustrating an example of the upper portion of the memory pillar MP, the contact plug CH, and the contact plug VY. FIG. 11 is a plan view of an upper end of the memory pillar MP. FIG. 12 is a plan view of an upper end of the contact plug CH.

First, the maximum value of the shift amount of the contact plug CH, that is, the maximum value of the CH shift amount will be described.

As illustrated in FIGS. 10 and 11, the diameter of the upper end of the memory pillar MP in the X direction is defined as Dmp. The diameter of the semiconductor film 41 in the X direction at the upper end of the memory pillar MP is Ds. The width of the stacked film 42 in the X direction at the upper end of the memory pillar MP is Wi. The diameter Dmp, the diameter Ds, and the width Wi have a relationship of Dmp=Ds+2Wi.

The diameter of the lower end of the contact plug CH in the X direction is defined as Dc_bm. The distance from the center axis CAm of the memory pillar MP to the center axis CAc of the contact plug CH, that is, the CH shift amount is Sf1. For example, in a case where (contact length between the upper surface of the semiconductor film 41 of the memory pillar MP and the bottom surface of the contact plug CH)>0 is satisfied, the CH shift amount Sf1 can be expressed as Sf1<(Ds+Dc_bm)/2.

Next, the maximum value of the misalignment amount of the contact plug VY with respect to the contact plug CH will be described. As illustrated in FIGS. 10 and 12, the diameter of the upper end of the contact plug CH in the X direction is defined as Dc_tp. The diameter of the lower end of the contact plug VY in the X direction is defined as Dv. A distance from the center axis CAc of the contact plug CH to a center axis CAv of the contact plug VY, that is, a misalignment amount of the contact plug VY with respect to the contact plug CH is Sf2. For example, in a case where (contact length between the upper surface of the contact plug CH and the bottom surface of the contact plug VY)>0 is satisfied, the shift amount Sf2 can be expressed as Sf2<(Dc_tp+Dv)/2.

### 5. Effects According to Present Embodiment

With the configuration according to the present embodiment, the semiconductor memory device can dispose the contact plug CH at a position where the center axis of the contact plug CH is shifted in the X direction from the center axis of the memory pillar MP. Furthermore, the semiconductor memory device can set the CH shift amounts of the five contact plugs CH corresponding to the five memory pillars MP arranged in five rows in a staggered manner in the X direction to different values in one string unit SU. Furthermore, the semiconductor memory device can make the amount of change in the CH shift amount of the contact plugs CH adjacent in the Y direction constant. As a result, the semiconductor memory device can suppress reduction in the contact area between the upper surface of the contact plug CH and the lower surface of the contact plug VY due to misalignment between the contact plug CH and the contact plug VY. That is, a coupling failure (contact failure) between the contact plug CH and the contact plug VY can be suppressed. Therefore, the reliability of the semiconductor memory device can be improved.

### 6. Modifications

The semiconductor memory device according to the above embodiment includes: a source line (32); a plurality of insulating layers (33) and a plurality of interconnect layers (34) provided on the source line and alternately stacked one by one; a plurality of memory pillars (MP) extending in a first (Z) direction, passing through the plurality of insulating layers and the plurality of interconnect layers, and having one end reaching the source line; a plurality of bit lines (BL) provided above the plurality of memory pillars, arranged side by side in a second (X) direction intersecting the first direction, and each extending in a third (Y) direction intersecting the first direction and the second direction; a plurality of first contact plugs (CH) provided on the plurality of memory pillars; a plurality of second contact plugs (VY) provided on the plurality of first contact plugs and each coupled to one of the plurality of bit lines; and a plurality of first members (SHE) arranged side by side in the second direction, each extending in the third direction, and separating, in the second direction, at least an interconnect layer (SGD) provided at a position farthest from the source line among the plurality of interconnect layers. The plurality of memory pillars include a first memory pillar (MP1), a second memory pillar (MP2), a third memory pillar (MP3), a fourth memory pillar (MP4), and a fifth memory pillar (MP5) arranged side by side in the third direction while alternately changing positions in the second direction in a first region (SU) between two first members adjacent in the third direction among the plurality of first members. The plurality of first contact plugs include a third contact plug (CH1) provided on the first memory pillar, a fourth contact plug (CH2) provided on the second memory pillar, a fifth contact plug (CH3) provided on the third memory pillar, a sixth contact plug (CH4) provided on the fourth memory pillar, and a seventh contact plug (CH5) provided on the fifth memory pillar. A first shift amount (A−2B) obtained by shifting the third contact plug in the second direction with respect to the first memory pillar, a second shift amount (A−B) obtained by shifting the fourth contact plug in the second direction with respect to the second memory pillar, a third shift amount (A) obtained by shifting the fifth contact plug in the second direction with respect to the third memory pillar, a fourth shift amount (A+B) obtained by shifting the sixth contact plug in the second direction with respect to the fourth memory pillar, and a fifth shift amount (A+2B) obtained by shifting the seventh contact plug in the second direction with respect to the fifth memory pillar are different from each other.

According to the configuration of the above embodiment, the semiconductor memory device can improve reliability.

Note that the present invention is not limited to the above-described embodiment, and various modifications can be applied.

For example, the memory cell array 11, the row decoder 12, the sense amplifier 13, the sequencer 21, and the voltage generator 22 may be formed on different semiconductor substrates. In this case, the semiconductor memory device 1 may be formed by bonding the respective substrates.

Furthermore, the “couple” in the above embodiments includes a state where coupling is indirectly made by interposing, for example, other components such as a transistor or a resistor between components to be coupled.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a source line;
a plurality of insulating layers and a plurality of interconnect layers provided on the source line and alternately stacked one by one;
a plurality of memory pillars extending in a first direction, passing through the plurality of insulating layers and the plurality of interconnect layers, and having one end reaching the source line;
a plurality of bit lines provided above the plurality of memory pillars, arranged side by side in a second direction intersecting the first direction, and each extending in a third direction intersecting the first direction and the second direction;
a plurality of first contact plugs provided on the plurality of memory pillars;
a plurality of second contact plugs provided on the plurality of first contact plugs and each coupled to one of the plurality of bit lines; and
a plurality of first members arranged side by side in the second direction, each extending in the third direction, and separating, in the second direction, at least an interconnect layer provided at a position farthest from the source line among the plurality of interconnect layers, wherein
the plurality of memory pillars include a first memory pillar, a second memory pillar, a third memory pillar, a fourth memory pillar, and a fifth memory pillar arranged side by side in the third direction while alternately changing positions in the second direction in a first region between two first members adjacent in the third direction among the plurality of first members,
the plurality of first contact plugs include a third contact plug provided on the first memory pillar, a fourth contact plug provided on the second memory pillar, a fifth contact plug provided on the third memory pillar, a sixth contact plug provided on the fourth memory pillar, and a seventh contact plug provided on the fifth memory pillar, and
a first shift amount obtained by shifting the third contact plug in the second direction with respect to the first memory pillar, a second shift amount obtained by shifting the fourth contact plug in the second direction with respect to the second memory pillar, a third shift amount obtained by shifting the fifth contact plug in the second direction with respect to the third memory pillar, a fourth shift amount obtained by shifting the sixth contact plug in the second direction with respect to the fourth memory pillar, and a fifth shift amount obtained by shifting the seventh contact plug in the second direction with respect to the fifth memory pillar are different from each other.

2. The semiconductor memory device according to claim 1, wherein
a difference between the first shift amount and the second shift amount, a difference between the second shift amount and the third shift amount, a difference between the third shift amount and the fourth shift amount, and a difference between the fourth shift amount and the fifth shift amount are the same.

3. The semiconductor memory device according to claim 1, wherein
an absolute value of the fifth shift amount is larger than an absolute value of the fourth shift amount.

4. The semiconductor memory device according to claim 1, wherein
the plurality of bit lines include a first bit line, a second bit line, a third bit line, a fourth bit line, and a fifth bit line arranged in order in the second direction,
the first memory pillar is electrically coupled to the first bit line,
the second memory pillar is electrically coupled to the fourth bit line,
the third memory pillar is electrically coupled to the second bit line,
the fourth memory pillar is electrically coupled to the fifth bit line, and
the fifth memory pillar is electrically coupled to the third bit line.

5. The semiconductor memory device according to claim 1, wherein
the first memory pillar includes a semiconductor film extending in the first direction, and
the first shift amount is less than a value obtained by adding a length of a first surface of the semiconductor film in contact with the third contact plug in the second direction and a length of a second surface of the third contact plug in contact with the semiconductor film in the second direction and dividing an added value by two.

6. The semiconductor memory device according to claim 1, wherein
the plurality of second contact plugs includes an eighth contact plug provided on the third contact plug, and
a sixth shift amount obtained by shifting the eighth contact plug in the second direction with respect to the third contact plug is less than a value obtained by adding a length of a third surface of the third contact plug in contact with the eighth contact plug in the second direction and a length of a fourth surface of the eighth contact plug in contact with the third contact plug in the second direction and dividing an added value by two.

7. The semiconductor memory device according to claim 1, wherein
the plurality of memory pillars further includes a sixth memory pillar, a seventh memory pillar, an eighth memory pillar, a ninth memory pillar, and a 10th memory pillar arranged side by side in the third direction while alternately changing positions in the second direction in a second region separated by the plurality of first members and adjacent to the first region, and
the plurality of first contact plugs further includes a ninth contact plug provided on the sixth memory pillar, a 10th contact plug provided on the seventh memory pillar, an 11th contact plug provided on the eighth memory pillar, a 12th contact plug provided on the ninth memory pillar, and a 13th contact plug provided on the 10th memory pillar, and
a seventh shift amount obtained by shifting the ninth contact plug in the second direction with respect to the sixth memory pillar, an eighth shift amount obtained by shifting the 10th contact plug in the second direction with respect to the seventh memory pillar, a ninth shift amount obtained by shifting the 11th contact plug in the second direction with respect to the eighth memory pillar, a 10th shift amount obtained by shifting the 12th contact plug in the second direction with respect to the ninth memory pillar, and an 11th shift amount obtained by shifting the 13th contact plug in the second direction with respect to the 10th memory pillar are different from each other.

8. The semiconductor memory device according to claim 7, wherein
a difference between the first shift amount and the second shift amount, a difference between the second shift amount and the third shift amount, a difference between the third shift amount and the fourth shift amount, a difference between the fourth shift amount and the fifth shift amount, a difference between the fifth shift amount and the seventh shift amount, a difference between the seventh shift amount and the eighth shift amount, a difference between the eighth shift amount and the ninth shift amount, a difference between the ninth shift amount and the 10th shift amount, and a difference between the 10th shift amount and the 11th shift amount are the same.

9. The semiconductor memory device according to claim 7, wherein
the plurality of bit lines include a first bit line, a second bit line, a third bit line, a fourth bit line, and a fifth bit line arranged side by side in the second direction,
the first memory pillar and the ninth memory pillar are electrically coupled to the first bit line,
the second memory pillar and the eighth memory pillar are electrically coupled to the fourth bit line,
the third memory pillar and the seventh memory pillar are electrically coupled to the second bit line,
the fourth memory pillar and the sixth memory pillar are electrically coupled to the fifth bit line, and
the fifth memory pillar and the 10th memory pillar are electrically coupled to the third bit line.

10. The semiconductor memory device according to claim 7, wherein
the plurality of memory pillars further include an 11th memory pillar, a 12th memory pillar, a 13th memory pillar, a 14th memory pillar, and a 15th memory pillar arranged side by side in the third direction while alternately changing positions in the second direction in a third region separated by the plurality of first members and adjacent to the second region,
the plurality of first contact plugs further include a 14th contact plug provided on the 11th memory pillar, a 15th contact plug provided on the 12th memory pillar, a 16th contact plug provided on the 13th memory pillar, a 17th contact plug provided on the 14th memory pillar, and a 18th contact plug provided on the 15th memory pillar,
a 12th shift amount obtained by shifting the 14th contact plug in the second direction with respect to the 11th memory pillar is the same as the first shift amount,
a 13th shift amount obtained by shifting the 15th contact plug in the second direction with respect to the 12th memory pillar is the same as the second shift amount,
a 14th shift amount obtained by shifting the 16th contact plug in the second direction with respect to the 13th memory pillar is the same as the third shift amount,
a 15th shift amount obtained by shifting the 17th contact plug in the second direction with respect to the 14th memory pillar is the same as the fourth shift amount, and
a 16th shift amount obtained by shifting the 18th contact plug in the second direction with respect to the 15th memory pillar is the same as the fifth shift amount.

11. The semiconductor memory device according to claim 1, wherein
each of the plurality of memory pillars includes:
a semiconductor film extending in the first direction; and
a stacked film having a side surface in contact with the semiconductor film and including a charge storage film.

12. A semiconductor memory device, comprising:
a plurality of interconnect layers that is stacked apart from each other in a first direction and each extends in a second direction intersecting the first direction;
a first memory pillar extending in the first direction and passing through the plurality of interconnect layers;
a second memory pillar disposed adjacent to the first memory pillar;
a plurality of bit lines provided above the first memory pillar and the second memory pillar, arranged side by side in the second direction, and each extending in a third direction intersecting the first direction and the second direction;
a first contact plug provided on the first memory pillar;
a second contact plug provided on the second memory pillar;
a third contact plug provided on the first contact plug and coupled to one of the plurality of bit lines; and
a fourth contact plug provided on the second contact plug and coupled to one of the plurality of bit lines, wherein
a first shift amount obtained by shifting the first contact plug in the second direction with respect to the first memory pillar and a second shift amount obtained by shifting the second contact plug in the second direction with respect to the second memory pillar are different.

13. The semiconductor memory device according to claim 12, further comprising:
a third memory pillar adjacent to the second memory pillar and provided at a position different from the first memory pillar in the third direction;
a fifth contact plug provided on the third memory pillar; and
a sixth contact plug provided on the fifth contact plug and coupled to one of the plurality of bit lines, wherein
a third shift amount obtained by shifting the fifth contact plug in the second direction with respect to the third memory pillar is different from the first shift amount and the second shift amount.

14. The semiconductor memory device according to claim 13, wherein
a difference between the first shift amount and the second shift amount is the same as a difference between the second shift amount and the third shift amount.
